(19) United States
(12) Patent Application Publication
(10) Pub. No.: US 2018/0116071 A1
(43) Pub. Date: Apr. 26, 2018

(54) ASSET MANAGEMENT MODULES

(71) Applicant: Hewlett-Packard Enterprise Development LP, Houston, TX (US)

(72) Inventors: Matthew E. Stevens, Houston, TX (US); Chris F. Felcman, Magnolia, TX (US)

(21) Appl. No.: 15/569,114

(22) PCT Filed: May 18, 2015
(86) PCT No.: PCT/US2015/031380

§ 371 Date: Oct. 25, 2017

(51) Int. Cl. H05K 7/14

(52) U.S. Cl. CPC H05K 7/1498

(57) ABSTRACT

Example implementations relate to asset management modules. For example, an asset management system includes an asset management module removably coupled to a rack. The module includes a plurality of data ports at each rack unit to receive a peripheral device associated with a computing device mounted in the rack. The asset management system also includes a controller communicatively coupled to the module. The controller is to collect data related to the computing device stored in the peripheral device.

### BACKGROUND

Asset management systems can be used to monitor and maintain computing components (i.e., assets) in a data center. For example, the computing components may include servers, modems, storage systems, routers, and other equipment, such as power, cooling, and cable management resources, among others. A rack enclosure may provide a standardized structure to support and mount the electronic components inside of the rack enclosure.

### BRIEF DESCRIPTION OF THE DRAWINGS

Some examples of the present application are described with respect to the following figures:

FIG. 1 is a block diagram of an example asset management system including an asset management module having a plurality of data ports;

FIG. 2 is a perspective view of a peripheral device inserted into an asset management module that is coupled to a rack, according to an example;

FIG. 3 is a perspective view of computing devices mounted in a rack and associated peripheral device inserted into an asset management module, according to an example; and

FIG. 4 is a flowchart of an example method for managing assets using an asset management module.

### DETAILED DESCRIPTION

Examples disclosed herein relate to asset management modules to capture asset information on rack mounted computing devices in a data center. The described examples can be used to capture information relating to a vendor's computing devices as well as third party computing devices. The asset management modules can be removably coupled to a rack and each include a plurality of data ports (e.g., universal serial bus (USB) ports) at each rack unit (i.e., “U”) location on the rack. The data ports are to receive peripheral devices (e.g., USB devices) containing information for respective computing devices mounted in the rack. A controller is provided to poll each data port on the rack to gather the asset information for each of the rack mounted computing devices and transmit the information to a data center information management (DCIM) and/or to a baseboard management controller (BMC). The information includes, but is not limited to, device identification (ID), serial number, a description of the computing device and/or type (e.g., server, storage, etc.), a rack unit height (e.g., 1 U, 2 U, 3 U, 4 U, etc.), an internet protocol (IP) address of the device, manufacturer/vendor identification and date of manufacture of the computing device.

In some example, where the computing device is owned by the vendor (i.e., not a third party device), the peripheral device can be pre-programmed with the device information. In other examples, where the computing device is a third party device, a programming engine can be provided to program the device information onto the peripheral device. In various examples, the peripheral devices are removably coupled or tethered to respective computing device and are inserted into the data ports when the computing devices are mounted into the rack. Accordingly, the described examples provide a cost effective intelligent asset management solution that also supports third party devices, removing a need for hardware design or chassis changes or firmware/application programming interface (API) script development to support third party devices, and provides an almost instant access to asset information once the device is mounted, amongst other advantages.

In one example, an asset management system includes an asset management module removably coupled to a rack. The module includes a plurality of data ports at each rack unit to receive a peripheral device associated with a computing device mounted in the rack. The asset management system also includes a controller communicatively coupled to the module. The controller is to collect data related to the computing device stored in the peripheral device.

In another example, a rack includes an asset management system. The asset management system includes a plurality of asset management modules removably coupled to a rack frame, where each module includes a plurality of data ports located at each rack unit. The asset management system includes a plurality of peripheral devices connected to data ports, each peripheral device associated with respective computing devices mounted in the rack, where each peripheral device includes data related to the respective computing devices. The asset management system also includes a controller communicatively coupled to the modules, the controller to receive the data via the modules.

In another example, a method includes coupling an asset management module to a rack frame, where the module includes a plurality of data ports located at each rack unit, and mounting a computing device into the rack. The method includes inserting a peripheral device associated with the computing device into a data port of the module, and extracting, by a controller, data stored on the peripheral device, where the data includes identification and location information of the computing device.

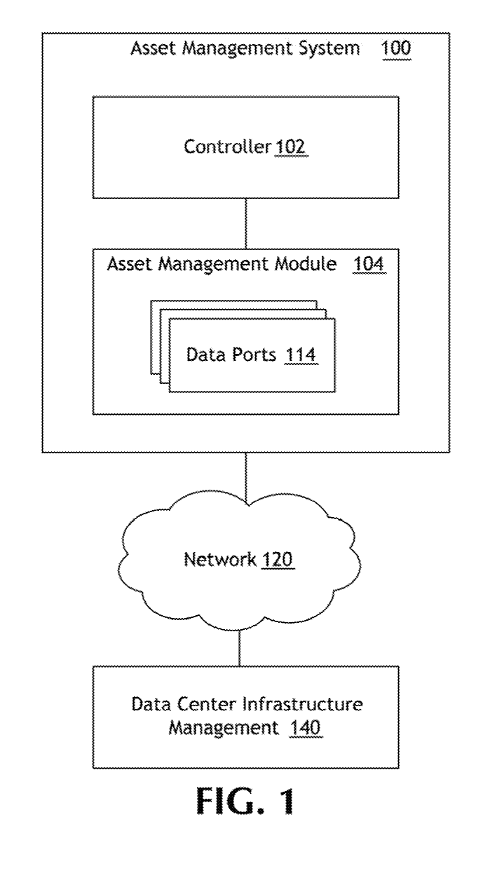

Referring now to the figures, FIG. 1 is a block diagram of an example asset management system including an asset management module having a plurality of data ports. Asset management system 100 can include a controller 102 and an asset management module 104 having a plurality of data ports 114. System 100 can be communicatively coupled to a data center infrastructure management (DCIM) 140 via a network 120. System 100 can include additional components other than those depicted in FIG. 1, such as embedded firmware and hardware components. For example, system 100 can include a central processing unit (CPU), display, other hardware, software application, (I/O) ports, peripheral devices, etc.

Controller 102 can include one or more CPUs or cores thereof, microprocessors, hardware state machines, graphic processing units (GPUs), field-programmable gate arrays (FGPAs), or other electronic circuitry, which may be integrated in a single device or distributed across devices. In some examples controller 102 may include one or more “lights-out” modules that may be powered on and operational when other modules or components of the system 100 are not powered on or are not operational. Controller 102 can be responsible for managing some or all of the functionalities of the system 100, including extracting asset information from the asset management module 104.

Asset management module 104 or module 104 can be a vertical management interface that can be removably coupled to a rack. Module 104 can include a front side and a back side opposite the front side. The front side of the module 104 can include the plurality of data ports 114 for receiving a plurality of peripheral devices. The back side of the module 104 can include a printed circuit assembly (PCA) or a printed circuit board (PCB) where all the electronic circuitry is housed. The PCA/PCB enables the module 104 to be communicatively coupled to another module and to the controller 102.

Module 104 can come in any rack unit (U) height such as 6 U, 7 U, 12 U, etc. In various examples, a plurality of modules 104 having varying U heights can be coupled to a rack of a particular U height. For example, in a 42 U rack, six 7 U modules 104 can be coupled to the rack, three 12 U modules 104 and one 6 U module 104 can be coupled to the rack, etc. Data ports 114 include receptacles and circuitry for receiving peripheral devices. Peripheral devices can include USB devices or any other low profile devices for storing asset information (i.e., data related to a computing device). The data ports 114 are located in each U location of the rack. For example, a 6 U module 104 will have 6 data ports 114, etc.

During operation, module 104 can be coupled to the rack and a computing devices such as, but not limited to, a servers, modems, networking devices, storage systems, routers, power devices, can be mounted in the rack. The computing device can have a peripheral device (e.g., a USB device) associated with the computing device coupled to (e.g., tethered) to the computing device. The peripheral device includes data related to the computing device. Once the computing device is mounted in the rack, the peripheral device can be inserted into a data port 114 of the module 104. Controller 102 can extract the data via the module 104. The data can include information such as device ID, serial number, a description of the computing device and/or type (e.g., server, storage, etc.), a rack unit height (e.g., 1 U, 2 U, 3 U, 4 U, etc.), IP address of the device, vendor or manufacturer ID, and date manufacturer or vendor ID and date of manufacture of the computing device.

In certain examples, the data related to the computing device can be pre-programmed onto the peripheral device. In other examples, asset management system 100 can include a programming engine for programming and entering data related to the computing device onto the peripheral device, for example where the computing device is a third party device. In such an example, programming engine can include a script to allow the user to enter data related to the computing device.

Controller 102 can transmit the data to a BMC of the rack and to a DCIM 120. DCIM 120 includes a category of solutions to extend data center management function to include all of the physical assets and resources found in the facilities and information technology (IT) domains. Controller can transmit the data to the DCIM over network 120. Network 120 can be any combination of local area networks, wide area networks, the Internet, wired, or wireless networks, or other types of networks. In some examples, network 120 can be a cloud network such as a public cloud network, a private cloud network, a hybrid cloud network, other forms of cloud networks, or combinations thereof. Controller 102 can transmit the data to the BMC using a wired or wireless connection.

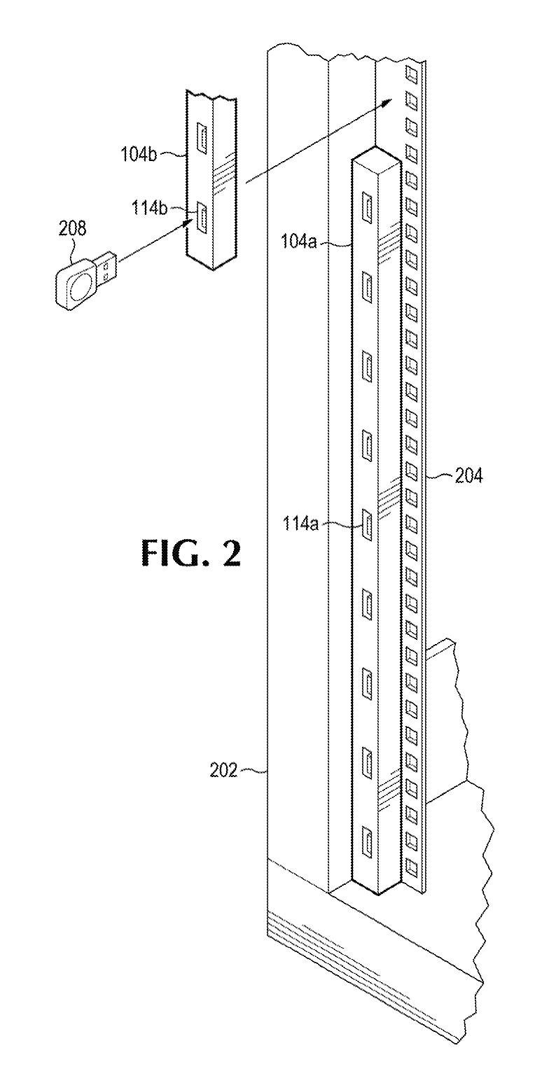

FIG. 2 is a perspective view of a peripheral device inserted into an asset management module that is coupled to a rack, according to an example. In the example of FIG. 2, two modules 104 can be removably coupled to a rack 202. Rack 202 includes a plurality of connectors 204 for mounting the modules 104. A first module 104a having nine data ports 114 is coupled to the rack 202. A second module 104b having data ports 114b can be removably coupled to the rack 202. A peripheral device 208 can be inserted into a data port 114b of the module 104b, as shown. Peripheral device 208 can be associated with a computing device (not shown) mounted in the rack 202 and include data related to the computing device.

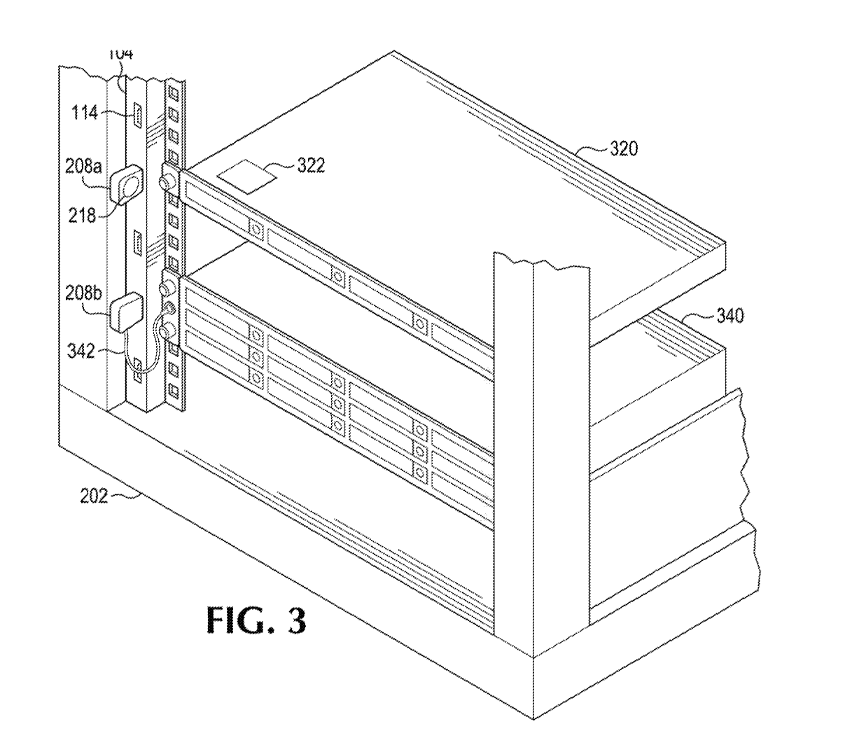

FIG. 3 is a perspective view of computing devices mounted in a rack and associated peripheral device inserted into an asset management module, according to an example. In the example of FIG. 3 a first computing device 320 (e.g., a server) and a second computing device 340 are mounted in the rack 202.

First device 320 is a 1 U device (i.e., rack height of 1 U) and device 340 is a 2 U device. First device 320 includes an attachment portion 322 for removably attaching peripheral device 208a that includes data related to first device 320. Attachment portion 322 can be, for example, a magnetic member, a Velcro strap, connector, or any other means for removably attaching the peripheral device 208a to first device 320. Peripheral device 208a can also include a corresponding attachment portion 218 for removably attaching to the attachment portion 322 of first device 320. Peripheral device 208b can be tethered to second device 340 using a tethering means 342. Peripheral device 208b includes data related to second device 340. When first device 320 and second device 340 are mounted into the rack 202, respective peripheral devices 208a and 208b can be inserted into data ports 114 of module 104. Controller 102 can extract the data from the peripheral devices 208a and 208b via the module 104.

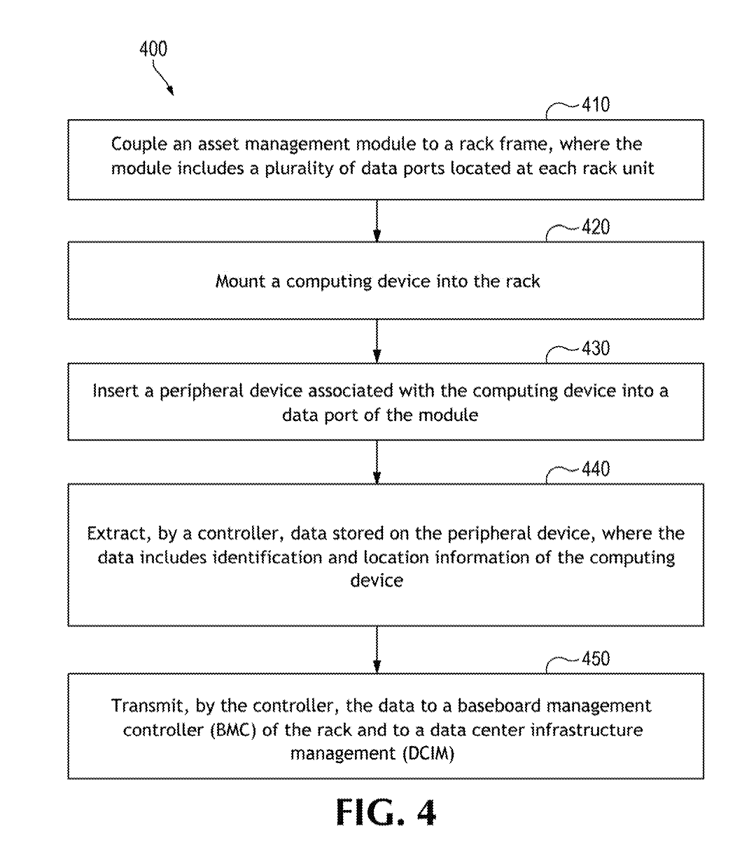

FIG. 4 is a flowchart of an example method for managing assets using an asset management module. Although execution of method 400 is described below with reference to system 100 of FIG. 1, other suitable devices for execution of method 400 can be used. Method 400 can be implemented in the form of executable instructions stored on a computer-readable storage medium and/or in the form of electronic circuitry.

Method 400 includes coupling an asset management module to a rack frame, where the module includes a plurality of data ports located at each rack unit, at 410. For example, module 104 can be removably coupled to a rack frame. Module 104 can include a plurality of data ports 114 at each rack unit to receive a plurality of peripheral devices.

Method 400 includes mounting a computing device into the rack, at 420. For example, a computing device such as a server device, networking device, storage device, etc. can be mounted into the rack.

Method 400 includes inserting a peripheral device associated with the computing device into a port of the module, at 430. For example, a peripheral device associated with the device and storing data related to the device can be inserted into one of the data ports 114 of the module 104.

Method 400 includes extracting, by a controller, data stored on the peripheral device, where the data includes identification and location information of the computing device, at 440. For example, controller 102 can extract the data stored on the peripheral device via the module 104. The data can include device ID, serial number, a description of the computing device and/or type (e.g., server, storage, etc.), a rack unit height (e.g., 1 U, 2 U, 3 U, 4 U, etc.), an IP address of the device, manufacturer/vendor identification and date of manufacture of the computing device, etc.

Method 400 includes transmitting, by the controller, the data to a baseboard management controller (BMC) of the rack and to a data center infrastructure management (DCIM), at 450. For example, the controller 102 can transmit the data to a BMC of the rack via wired or wireless transmission, and transmit the data to a DCIM over a network. In some examples, the method 400 of FIG. 4 includes additional steps in addition to and/or in lieu of those depicted in FIG. 4.

The techniques described above may be embodied in a computer-readable medium for configuring a computing system to execute the method. The computer-readable media may include, for example and without limitation, any number of the following non-transitive mediums: magnetic storage media including disk and tape storage media; optical storage media such as compact disk media (e.g., CD-ROM, CD-R, etc.) and digital video disk storage media; holographic memory; nonvolatile memory storage media including semiconductor-based memory units such as FLASH memory, EEPROM, EPROM, ROM; ferromagnetic digital memories; volatile storage media including registers, buffers or caches, main memory, RAM, etc.; and the Internet, just to name a few. Other new and obvious types of computer-readable media may be used to store the software modules discussed herein. Computing systems may be found in many forms including but not limited to mainframes, minicomputers, servers, workstations, personal computers, notepads, personal digital assistants, tablets, smartphones, various wireless devices and embedded systems, just to name a few.

What is claimed is:

1. An asset management system, comprising:
an asset management module removably coupled to a rack, the module comprising a plurality of data ports at each rack unit to receive a peripheral device associated with a computing device mounted in the rack; and
a controller communicatively coupled to the module, the controller to collect data related to the computing device stored in the peripheral device.

2. The system of claim 1, wherein the management controller is to transmit the data to a data center infrastructure management (DCIM) over a network.

3. The system of claim 1, wherein the data includes at least one of a device identification (ID), a serial number, a description, a rack unit height, an internet protocol (IP) address, and manufacturer identification and date of manufacture of the computing device.

4. The system of claim 1, wherein the controller is to transmit the data to a baseboard management controller (BMC) of the rack.

5. The system of claim 1, wherein the controller is to poll the data from the peripheral device via the module.

6. The system of claim 1, wherein the peripheral device is pre-programmed with the data.

7. The system of claim 1, comprising a programming engine to program data related to the computing device onto the peripheral device.

8. The system of claim 1, wherein the peripheral device is removably coupled to the computing device.

9. The system of claim 1, comprising:
a second asset management module removably coupled to the rack, the second module comprising a plurality of data ports at each rack unit to receive a second peripheral device associated with a second computing device mounted in the rack,
wherein the second module is communicatively coupled to the first module and to the controller, and
wherein the controller is to collect data related to the second computing device from the second peripheral device via the second module.

10. A rack, comprising:
an asset management system, comprising:
a plurality of asset management modules removably coupled to a rack frame, wherein each module comprises a plurality of data ports located at each rack unit;
a plurality of peripheral devices connected to the data ports, each peripheral devices associated with respective computing devices mounted in the rack, wherein each peripheral device includes data related to the respective computing devices; and
a controller communicatively coupled to the modules, the controller to receive the data via the modules.

11. The rack enclosure of claim 10, wherein each modules comprises:
a front side comprising the data ports; and
a back side comprising a printed circuit assembly (PCA), wherein the PCA is to read the data from the peripheral devices and to send the data to the controller,
wherein the modules are connected to each other and to the controller via the PCA.

12. The rack enclosure of claim 10, comprising a programming engine to program data related to the computing devices on respective peripheral devices.

13. The rack enclosure of claim 10, wherein the peripheral devices include a universal serial bus (USB) device for storing data related to the computing devices and wherein each USB device is removably tethered to a respective computing device.

14. A method, comprising:
coupling an asset management module to a rack frame, wherein the module includes a plurality of data ports located at each rack unit;
mounting a computing device into the rack;
inserting a peripheral device associated with the computing device into a data port of the module; and
extracting, by a controller, data stored on the peripheral device, wherein the data includes identification and location information of the computing device.

15. The method of claim 1, comprising transmitting, by the controller, the data to a baseboard management controller (BMC) of the rack and to a data center infrastructure management (DCIM).
